(19) United States
(12) Patent Application Publication
(10) Pub. No.: US 2026/0227466 A1
(43) Pub. Date: Aug. 6, 2026

(54) INSPECTION DEVICE, INSPECTION METHOD, AND METHOD FOR MANUFACTURING BATTERY

(71) Applicant: KABUSHIKI KAISHA TOSHIBA, Kawasaki-shi Kanagawa (JP)

(72) Inventors: Yoshihiro HIGASHI, Komatsu Ishikawa (JP); Akira KIKITSU, Yokohama Kanagawa (JP); Satoshi SHIROTORI, Yokohama Kanagawa (JP)

(73) Assignee: KABUSHIKI KAISHA TOSHIBA, Kawasaki-shi Kanagawa (JP)

(21) Appl. No.: 19/462,193

(22) Filed: Jan. 28, 2026

(30) Foreign Application Priority Data
Feb. 3, 2025 (JP) 2025-016385

(51) Int. Cl. G01R 33/10; G01R 33/02; G01R 33/12; H01M 10/48

(52) U.S. Cl. CPC G01R 33/10; G01R 33/0206; G01R 33/12; H01M 10/48

(57) ABSTRACT

According to one embodiment, an inspection device includes a processor configured to perform a first operation. The data includes a first magnetic field data related to a first plane, and a second magnetic field data related to a second plane. The first plane includes a first region and a first other region. The first magnetic field data includes a first region data related to the first region and a first other region data related to the first other region. The processor inspects the inspection target based on derived data in the first operation. The derived data includes a first inspection data including a first difference between the first region data and a first other region inverted data obtained by inverting a first other magnetic field value included in the first other region data in the first direction, and a second inspection data based on the second magnetic field data.

### CROSS-REFERENCE TO RELATED APPLICATIONS

This application is based upon and claims the benefit of priority from Japanese Patent Application No. 2025-016385, filed on February 3, 2025; the entire contents of which are incorporated herein by reference.

### FIELD

Embodiments described herein relate generally to an inspection device, an inspection method, and a method for manufacturing a battery.

### BACKGROUND

For example, an inspection target such as a battery is inspected by detecting a magnetic field generated from the inspection target. Higher accuracy of the inspection is desired.

### BRIEF DESCRIPTION OF THE DRAWINGS

FIGS. 1A and 1B are schematic diagrams illustrating an inspection device according to a first embodiment;

FIG. 2 is a flowchart illustrating the operation of the inspection device according to the first embodiment;

FIG. 3 is a schematic diagram illustrating the inspection device according to the first embodiment;

FIG. 4 is a schematic diagram illustrating the inspection device according to the first embodiment;

FIG. 5 is a schematic diagram illustrating the inspection device according to the first embodiment;

FIG. 6 is a schematic diagram illustrating the inspection device according to the first embodiment;

FIG. 7 is a schematic diagram illustrating the inspection device according to the first embodiment;

FIG. 8 is a schematic diagram illustrating the inspection device according to the first embodiment;

FIG. 9 is a schematic diagram illustrating the inspection device according to the first embodiment;

FIG. 10 is a schematic diagram illustrating the inspection device according to the first embodiment;

FIG. 11 is a schematic diagram illustrating the inspection device according to the first embodiment;

FIG. 12 is a schematic diagram illustrating the inspection device according to the first embodiment; and

FIG. 13 is a flow chart illustrating a method for manufacturing a battery according to a third embodiment.

### DETAILED DESCRIPTION

According to one embodiment, an inspection device includes an acquisitor configured to acquire data obtained from an inspection target, and a processor configured to perform a first operation of processing the data acquired by the acquisitor. The data includes a first magnetic field data related to a first plane, and a second magnetic field data related to a second plane. The first plane is along a first direction and a second direction crossing the first direction. The second plane is along the second direction and a third direction. The third direction crosses a plane including the first direction and the second direction. The first plane includes a first region and a first other region. A direction from the first region to the first other region is along the first direction. The first magnetic field data includes a first region data related to the first region and a first other region data related to the first other region. The processor is configured to inspect the inspection target based on derived data in the first operation. The derived data includes a first inspection data including a first difference between the first region data and a first other region inverted data obtained by inverting a first other magnetic field value included in the first other region data in the first direction, and a second inspection data based on the second magnetic field data.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

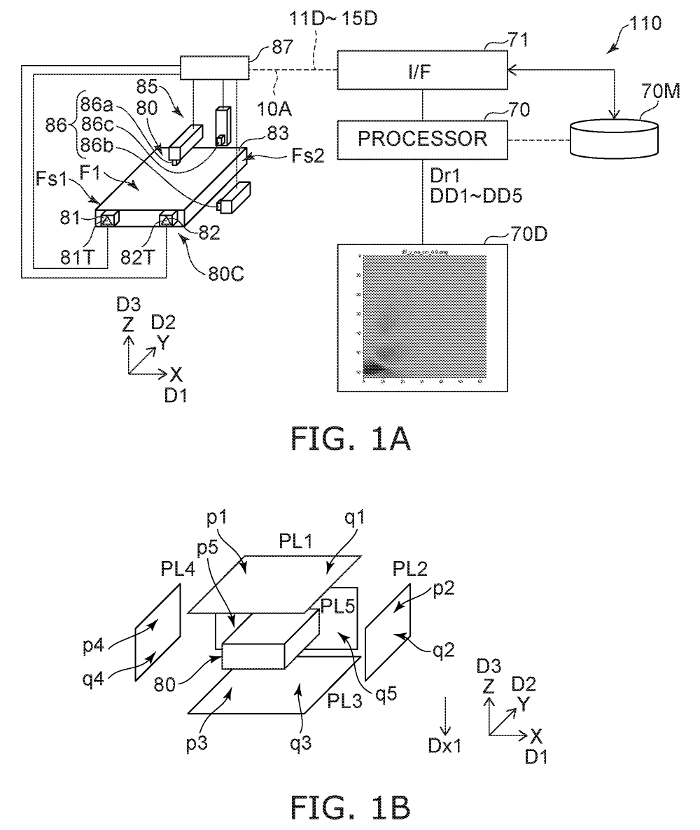

FIGS. 1A and 1B are schematic diagrams illustrating an inspection device according to the first embodiment.

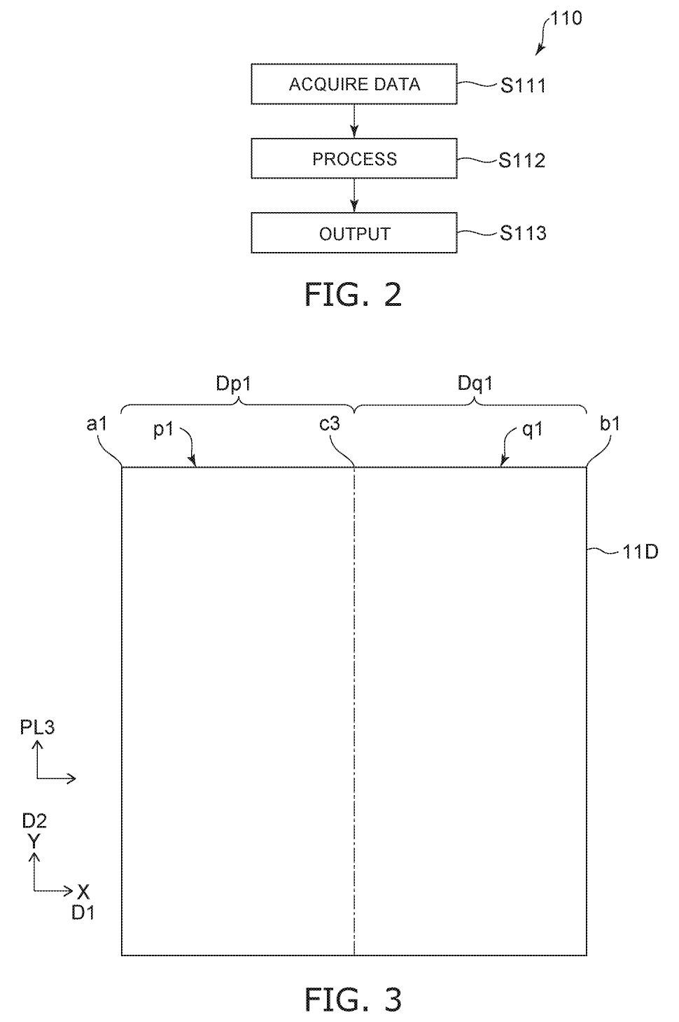

FIG. 2 is a flowchart illustrating the operation of the inspection device according to the first embodiment.

FIG. 3 is a schematic diagram illustrating the inspection device according to the first embodiment.

As shown in FIG. 1, an inspection device 110 according to the embodiment includes an acquisitor 71 and a processor 70. The acquisitor 71 is configured to acquire data 10A obtained from the inspection target 80. The processor 70 is configured to perform a first operation of processing the data 10A acquired by the acquisitor 71. The acquisitor 71 is, for example, an interface. The processor 70 may be, for example, a processing circuit (e.g., an electrical circuit). The processor 70 is configured to inspect the inspection target 80 based on derived data Dr1 in the first operation.

FIG. 2 illustrates an example of an inspection method performed by the inspection device 110. As shown in FIG. 2, for example, the acquisitor 71 acquires data 10A (step S111). For example, the processor 70 processes the data 10A (step S112). For example, the processor 70 outputs a processing result (step S113). The processing result includes an inspection result.

In one example, the inspection target 80 may be a battery 80C. The battery 80C may include, for example, a first electrode 81, a second electrode 82, and a battery portion 83. The battery portion 83 is provided, for example, between the first electrode 81 and the second electrode 82.

In one example, in testing the battery 80C, a voltage is applied between first electrode 81 and second electrode 82. The application of the voltage causes a current to flow between first electrode 81 and second electrode 82. The current generates a magnetic field. The generated magnetic field is detected by a magnetic field sensor 85. The magnetic field sensor 85 may include a sensor element 86 and a controller 87. The relative position between the sensor element 86 and the inspection target 80 is changed.

In this example, the sensor element 86 includes a first sensor element 86a, a second sensor element 86b, and a third sensor element 86c. The first sensor element 86a detects a magnetic field, for example, along a plane. The second sensor element 86b detects a magnetic field, for example, along another plane. The third sensor element 86c detects a magnetic field, for example, along yet another plane. Each of the first sensor element 86a, the second sensor element 86b, and the third sensor element 86c may be scanned. Alternatively, each of the first sensor element 86a, the second sensor element 86b, and the third sensor element 86c may include multiple elements.

The controller 87 may be configured, for example, to control changes in the relative position between the sensor element 86 and the inspection target 80. The controller 87 may be configured, for example, to control the orientation of the sensor element 86. The sensor element 86 may be configured to detect a magnetic field in any direction. The controller 87 may be configured, for example, to process a signal obtained from the sensor element 86. The signal processing may include, for example, amplification. The signal processing may include any processing including, for example, A/D conversion. The above magnetic field data (such as the first magnetic field data 11D and the second magnetic field data 12D) is supplied, for example, from the controller 87 to the acquisitor 71.

Communication (data transmission and reception) between the magnetic field sensor 85 and the acquisitor 71 can be performed by any wired or wireless method. The magnetic field data can be stored in, for example, the storage 70M.

The magnetic field sensor 85 is configured to acquire first magnetic field data 11D and second magnetic field data 12D from the inspection target 80. The magnetic field sensor 85 may be further configured to acquire third magnetic field data 13D and fourth magnetic field data 14D from the inspection target 80. The magnetic field sensor 85 may be further configured to acquire fifth magnetic field data 15D from the inspection target 80. These magnetic field data may be two-dimensional data.

The data 10A includes the first magnetic field data 11D related to a first plane PL1 and the second magnetic field data 12D related to a second plane PL2. The data 10A may further include the third magnetic field data 13D related to a third plane PL3. The data 10A may further include the fourth magnetic field data 14D related to a fourth plane PL4. The data 10A may further include the fifth magnetic field data 15D related to a fifth plane PL5.

As shown in FIG. 1B, the first plane PL1 is along the first direction D1 and the second direction D2 crossing the first direction D1. The second plane PL2 is along the second direction D2 and a third direction D3. The third direction D3 crosses a plane including the first direction D1 and the second direction D2.

The first direction D1 is defined as an X-axis direction. One direction perpendicular to the X-axis direction is defined as a Y-axis direction. A direction perpendicular to the X-axis direction and the Y-axis direction is defined as a Z-axis direction. The second direction D2 may be, for example, the Y-axis direction. The third direction D3 may be, for example, the Z-axis direction.

As already described, in the first operation, the processor 70 is configured to inspect the inspection target 80 based on the derived data Dr1 (see FIG. 1A). The derived data Dr1 includes a first inspection data DD1 and a second inspection data DD2. The first inspection data DD1 is derived from the first magnetic field data 11D. The second inspection data DD2 is based on the second magnetic field data 12D.

FIG. 3 shows a schematic example of the regions related to the first magnetic field data 11D being of two-dimensional. As shown in FIG. 1B and FIG. 3, the first plane PL1 includes a first region p1 and a first other region q1. A direction from the first region p1 to the first other region q1 is along the first direction D1. The first magnetic field data 11D includes a first region data Dp1 related to the first region p1 and a first other region data Dq1 related to the first other region q1.

The first inspection data DD1 includes a first difference between a first other region inverted data obtained by inverting a first other magnetic field value included in the first other region data Dq1 in the first direction D1, and the first region data Dp1.

By using the first inspection data DD1 including the first difference between the first other region inverted data and the first region data Dp1, the position of the abnormal portion of the inspection target 80 can be estimated with high accuracy. By further using the second inspection data DD2 based on the second magnetic field data 12D related to a different plane, the position of the abnormal portion of the inspection target 80 can be detected with high accuracy.

For example, there are cases where the difference in the detected magnetic field is small between the normal portion and the abnormal portion of the inspection target 80, making it difficult to distinguish between the signal caused by the abnormal portion and the noise. In such a case, it is difficult to detect the abnormal portion based on the magnitude of the value of the detected magnetic field. Furthermore, in a case where electrodes or the like are provided in the inspection target 80 and the current path has a peculiar shape, it may be difficult to distinguish between the abnormal portion and the peculiar shape of the current path.

In the embodiment, the difference between the inverted magnetic field data obtained by inverting the magnetic field data of the first other region q1 and the magnetic field data of the first region p1 is calculated. This suppresses the effects of noise. This suppresses the effects of the peculiar shape of the current path. This allows the position of the abnormal portion in the first plane PL1 to be detected with high sensitivity. In a case where only the first inspection data DD1 related to the first plane PL1 is used, it is difficult to distinguish whether the abnormal portion is present in the first region p1 or the first other region q1. In the embodiment, in addition to the first inspection data DD1, the second inspection data DD2 is used. This allows, for example, the position of the abnormal portion to be accurately detected. According to the embodiment, an inspection device capable of highly accurate inspection can be provided.

An example of data inversion will be described below.

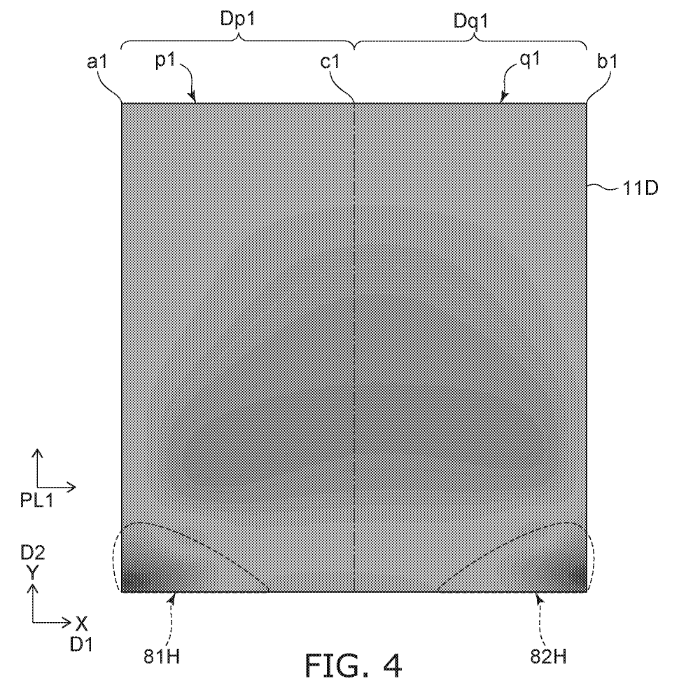

FIGS. 4 to 6 are schematic diagrams illustrating the inspection device according to the first embodiment.

FIG. 4 shows a schematic example of two-dimensional first magnetic field data 11D. As already described, the two-dimensional first magnetic field data 11D relates to the first plane PL1 including the first direction D1 and the second direction D2. In FIG. 4, the magnetic field strength in the first direction D1 and the second direction D2 is shown by the shading of the image.

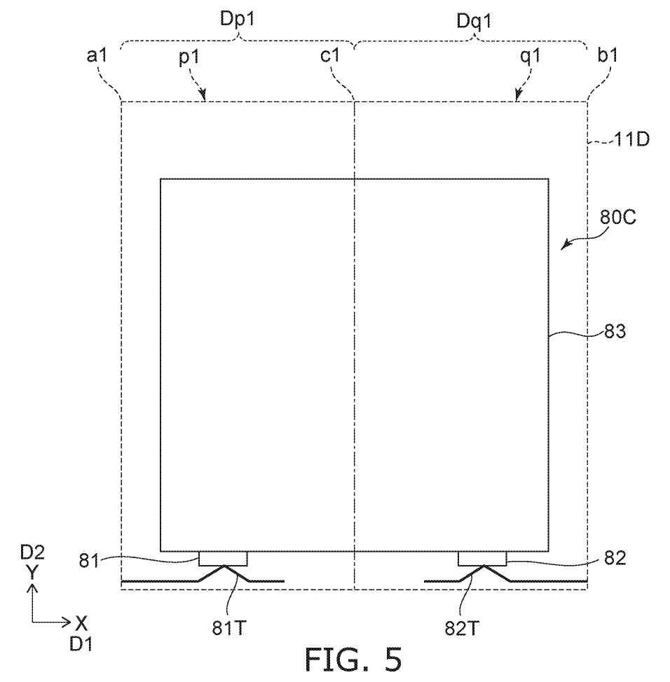

FIG. 5 shows the positional relationship between the two-dimensional first magnetic field data 11D and the battery 80C in this example. As shown in FIG. 5, the first magnetic field data 11D may include information about the magnetic field in a region larger than the battery 80C.

As shown in FIGS. 4 and 5, the first magnetic field data 11D obtained from the inspection target 80 may include a magnetic field caused by a terminal that supplies a voltage (signal) to the first electrode 81 and the second electrode 82. In this example, the first magnetic field data 11D being two-dimensional includes a first terminal magnetic field 81H caused by the first terminal 81T electrically connected to the first electrode 81, and a second terminal magnetic field 82H caused by the second terminal 82T electrically connected to the second electrode 82.

As shown in FIG. 4, the first plane PL1 includes the first region p1 and the first other region q1. The direction from the first region p1 to the first other region q1 is along the first direction D1. The first magnetic field data 11D includes the first region data Dp1 related to the first region p1 and the first other region data Dq1 related to the first other region q1.

As shown in FIG. 4, the first plane PL1 includes a first position a1, a first opposing position b1, and a first other position c1. For example, the first other position c1 may be a first midpoint between the first position a1 and the first opposing position b1 in the first direction D1. The first region p1 is between the first position a1 and the first other position c1 in the first direction D1. The first other region q1 is between the first other position c1 and the first opposing position b1 in the first direction D1.

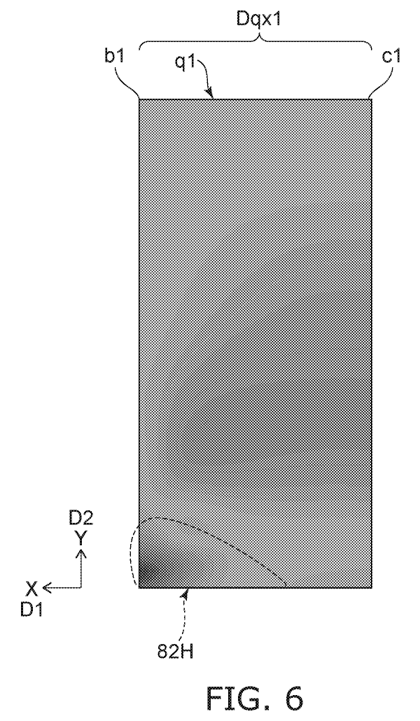

FIG. 6 illustrates the first other region inverted data Dqx1 obtained by inverting the first other magnetic field value included in the first other region data Dq1 in the first direction D1. In the first other region inverted data Dqx1, the first other region data Dq1 illustrated in FIG. 4 is inverted with respect to the first direction D1. Difference data between such first other region inverted data Dqx1 (FIG. 6) and the first region data Dp1 (see FIG. 4) is calculated. For example, a case where the difference data exceeds a threshold value is determined that there is a defect.

In the embodiment, the second inspection data DD2 may include inverted data obtained by inverting a part of the data included in the second magnetic field data 12D.

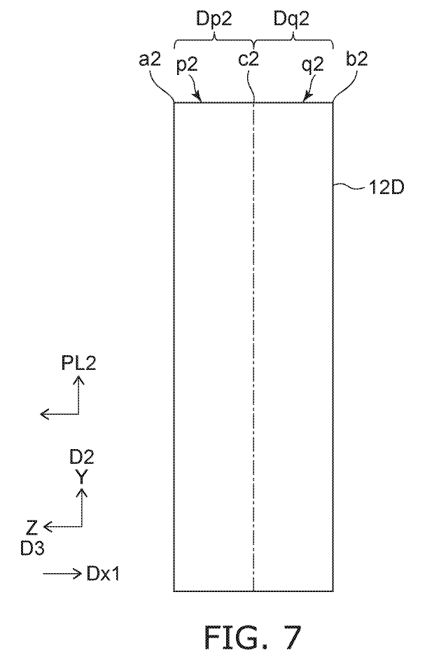

FIG. 7 is a schematic diagram illustrating the inspection device according to the first embodiment.

FIG. 7 illustrates an example of a region related to the second magnetic field data 12D on the second plane PL2. The second plane PL2 includes a second region p2 and a second other region q2. The direction from the second region p2 to the second other region q2 is along a first crossing direction Dx1 that crosses the first direction D1 (see FIG. 1B). The first crossing direction Dx1 may be, for example, a direction along the Z-axis direction.

The second magnetic field data 12D includes a second region data Dp2 related to the second region p2 and a second other region data Dq2 related to the second other region q2. The second inspection data DD2 includes a second difference between second other region inverted data obtained by inverting a second other magnetic field value included in the second other region data Dq2 in the first crossing direction Dx1 and the second region data Dp2. The position of the abnormal portion can be detected with high sensitivity from the second magnetic field data 12D related to the second plane PL2. The position of the abnormal portion can be detected with high accuracy.

As shown in FIG. 7, the second plane PL2 may include a second position a2, a second opposing position b2, and a second other position c2. The second other position c2 may be a second midpoint between the second position a2 and the second opposing position b2 in the first crossing direction Dx1. The second region p2 is between the second position a2 and the second other position c2 in the first crossing direction Dx1. The second other region q2 is between the second other position c2 and the second opposing position b2 in the first crossing direction Dx1.

As already described, the data 10A may further include the third magnetic field data 13D related to the third plane PL3 (see FIG. 1B).

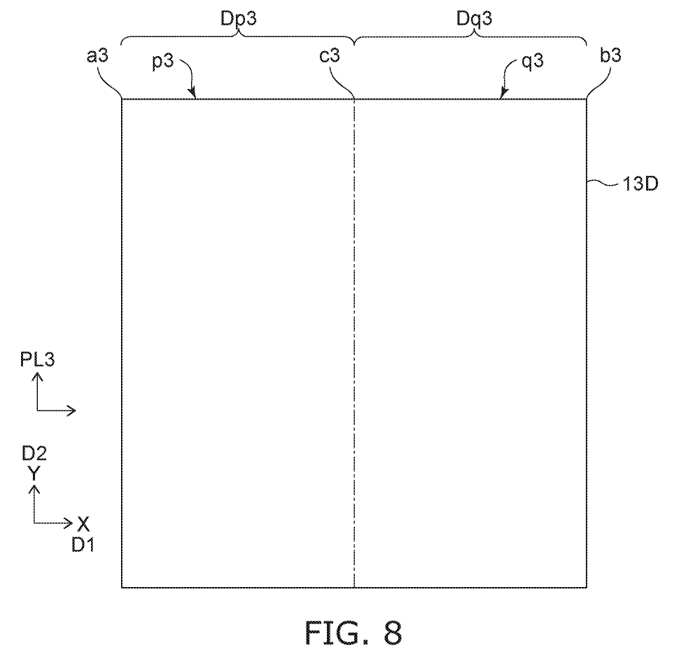

FIG. 8 is a schematic diagram illustrating the inspection device according to the first embodiment.

FIG. 8 illustrates a region related to the third magnetic field data 13D related to the third plane PL3. The third plane PL3 is along the first direction D1 and the second direction D2. The inspection target 80 is between the first plane PL1 and the third plane PL3 (see FIG. 1B).

As shown in FIG. 8, the third plane PL3 includes a third region p3 and a third other region q3. The direction from the third region p3 to the third other region q3 is along the first direction D1. The third magnetic field data 13D includes a third region data Dp3 related to the third region p3 and a third other region data Dq3 related to the third other region q3.

The derived data Dr1 (see FIG. 1A) further includes a third inspection data DD3. The third inspection data DD3 includes a third difference between the third other region data Dp3 and the third other region inverted data obtained by inverting the third other magnetic field value included in the third other region data Dq3 in the first direction D1. By using such third inspection data DD3, it is possible to perform inspection with higher accuracy.

As shown in FIG. 8, the third plane PL3 may include a third position a3, a third opposing position b3, and a third other position c3. The third other position c3 may be a third midpoint between the third position a3 and the third opposing position b3 in the first direction D1. The third region p3 is between the third position a3 and the third other position c3 in the first direction D1. The third other region q3 is between the third other position c3 and the third opposing position b3 in the first direction D1.

As already described, the data 10A may further include the fourth magnetic field data 14D related to the fourth plane PL4 (see FIG. 1B).

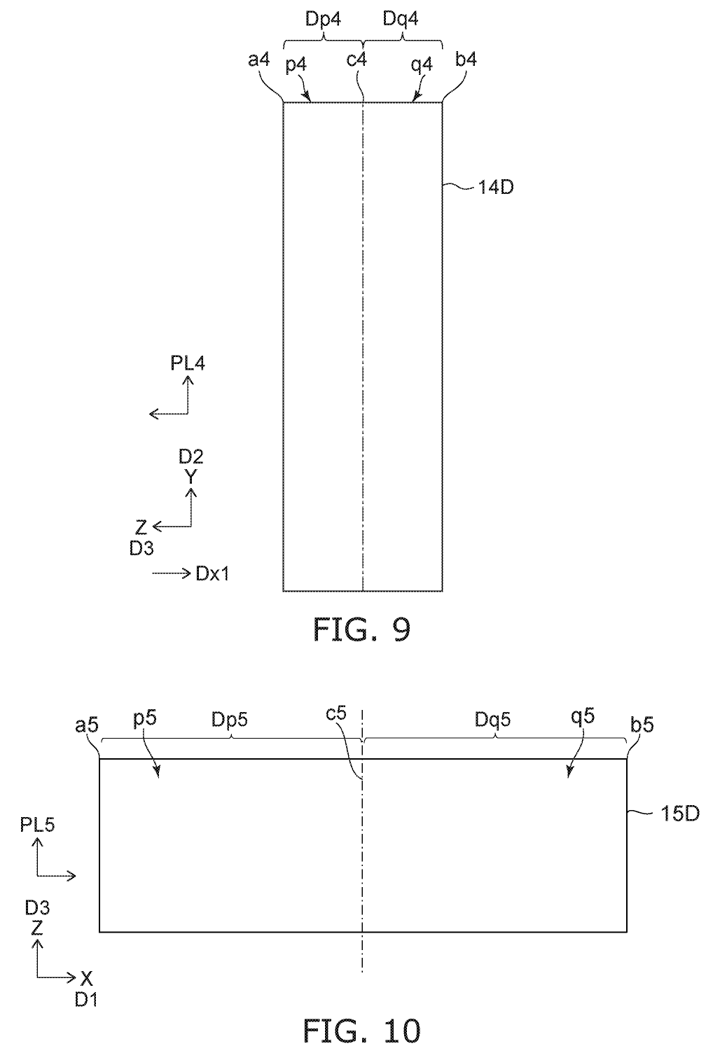

FIG. 9 is a schematic diagram illustrating the inspection device according to the first embodiment.

FIG. 9 illustrates a region related to the fourth magnetic field data 14D related to the fourth plane PL4. The fourth plane PL4 is along the second direction D2 and the third direction D3. The inspection target 80 is between the fourth plane PL4 and the second plane PL2 (see FIG. 1B).

As shown in FIG. 9, the fourth plane PL4 includes a fourth region p4 and a fourth other region q4. The direction from the fourth region p4 to the fourth other region q4 is along the first crossing direction Dx1. The fourth magnetic field data 14D includes a fourth region data Dp4 related to the fourth region p4 and a fourth other region data Dq4 related to the fourth other region q4. The derived data Dr1 may include a fourth inspection data DD4.

The fourth inspection data DD4 (see FIG. 1A) includes a fourth difference between a fourth other region inverted data obtained by inverting a fourth other-magnetic-field value included in the fourth other region data Dq4 in the first crossing direction Dx1 and the fourth region data Dp4. By using such fourth inspection data DD4, it is possible to perform inspection with higher accuracy.

As shown in FIG. 9, the fourth plane PL4 includes a fourth position a4, a fourth opposing position b4, and a fourth other position c4. The fourth other position c4 may be a fourth midpoint between the fourth position a4 and the fourth opposing position b4 in the first crossing direction Dx1. The fourth region p4 is between the fourth position a4 and the fourth other position c4 in the first crossing direction Dx1. The fourth other region q4 is between the fourth other position c4 and the fourth opposing position b4 in the first crossing direction Dx1.

In the embodiment, the data 10A may include first magnetic field data 11D related to the first plane PL1 and third magnetic field data 13D related to the third plane PL3. In this case, the data 10A may not include second magnetic field data 12D related to the second plane PL2.

In the embodiment, the first magnetic field data 11D may include data related to a component in the second direction D2. The second magnetic field data 12D may include data related to a component in the second direction D2.

As already described, the data 10A may further include the fifth magnetic field data 15D related to the fifth plane PL5 (see FIG. 1B).

FIG. 10 is a schematic diagram illustrating the inspection device according to the first embodiment.

FIG. 10 illustrates a region related to the fifth magnetic field data 15D related to the fifth plane PL5. The fifth plane PL5 is along the first direction D1 and the third direction D3. The direction from the inspection target 80 to the fifth plane PL5 is along the second direction D2. The battery portion 83 is between the first electrode 81 and the fifth plane PL5, and between the second electrode 82 and the fifth plane PL5 (see FIG. 1B).

As shown in FIG. 10, the fifth plane PL5 includes a fifth region p5 and a fifth other region q5. The direction from the fifth region p5 to the fifth other region q5 is along the first direction D1. The fifth magnetic field data 15D includes a fifth region data Dp5 related to the fifth region p5 and a fifth other region data Dq5 related to the fifth other region q5. The derived data Dr1 may include a fifth inspection data DD5.

The fifth inspection data DD5 (see FIG. 1A) includes a fifth difference between the fifth other region data Dp5 and the fifth other region inverted data obtained by inverting a fifth other magnetic field value included in the fifth other region data Dq5 in the first direction D1. By using such fifth inspection data DD5, it is possible to perform inspection with higher accuracy.

As shown in FIG. 10, the fifth plane PL5 includes a fifth position a5, a fifth opposing position b5, and a fifth other position c5. The fifth other position c5 may be a fifth midpoint between the fifth position a5 and the fifth opposing position b5 in the first direction D1. The fifth region p5 is between the fifth position a5 and the fifth other position c5 in the first direction D1. The fifth other region q5 is between the fifth other position c5 and the fifth opposing position b5 in the first direction D1.

An example of processing in the embodiment will now be described.

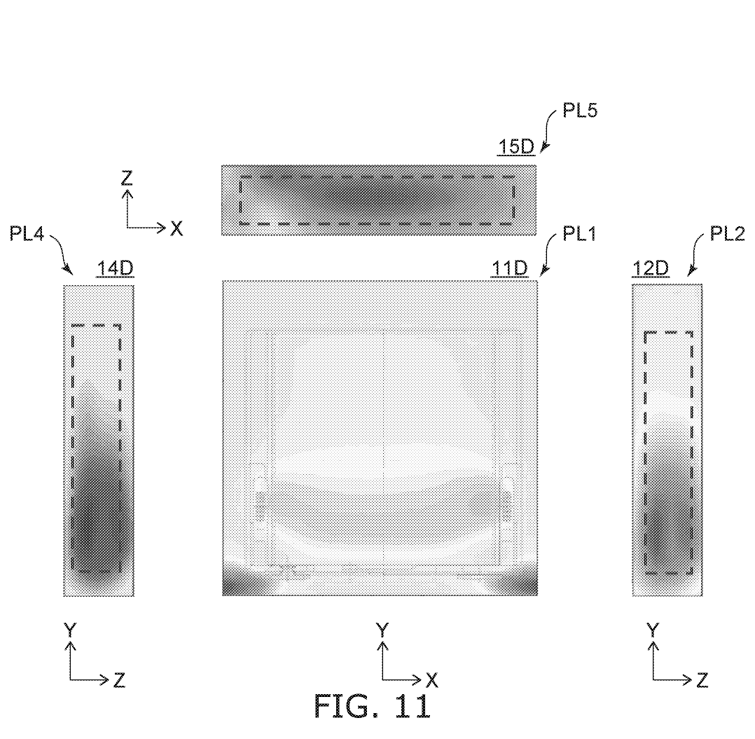

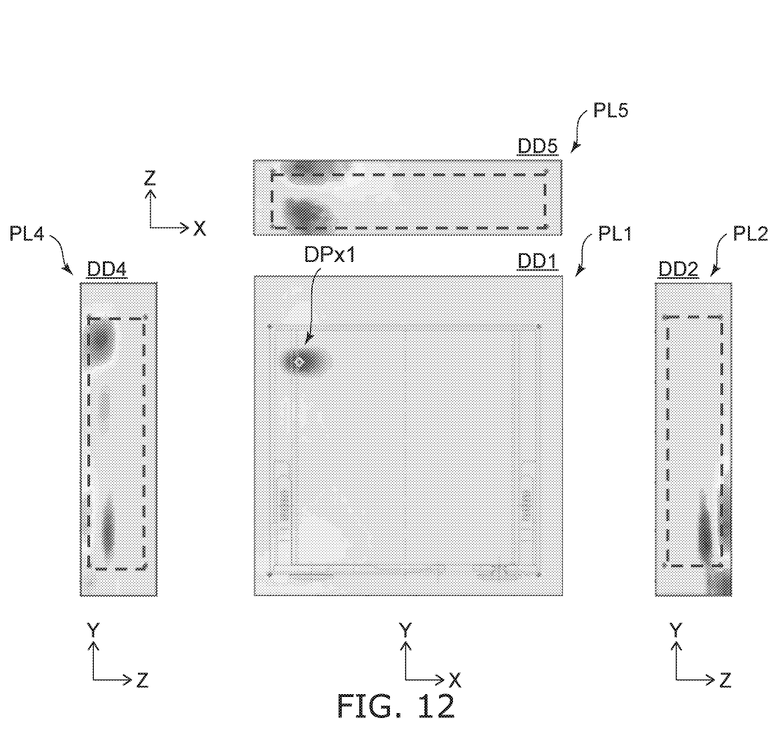

FIGS. 11 and 12 are schematic diagrams illustrating the inspection device according to the first embodiment.

FIG. 11 illustrates the first magnetic field data 11D, the second magnetic field data 12D, the fourth magnetic field data 14D, and the fifth magnetic field data 15D. The first magnetic field data 11D relates to the first plane PL1. The second magnetic field data 12D relates to the second plane PL2. The fourth magnetic field data 14D relates to the fourth plane PL4. The fifth magnetic field data 15D relates to the fifth plane PL5. In FIG. 11, the magnetic field strength is shown by the shading of the image. FIG. 11 corresponds to the data before inversion processing.

FIG. 12 illustrates the first inspection data DD1, the second inspection data DD2, the fourth inspection data DD4, and the fifth inspection data DD5. These inspection data include the differences between the other region inverted data and the first region data in the first plane PL1, the second plane PL2, the fourth plane PL4, and the fifth plane PL5. In FIG. 12, the magnetic field strength is shown by the shading of the image. As shown in FIG. 12, a position DPx1 where a large local change in image density is observed. This position DPx1 corresponds to, for example, the position of a defect.

### Second Embodiment

The second embodiment relates to an inspection method. In the inspection method, data 10A obtained from the inspection target 80 is acquired (step S111 in FIG. 2). The data 10A is processed (step S112 in FIG. 2).

The data 10A includes the first magnetic field data 11D related to the first plane PL1 and the second magnetic field data 12D related to the second plane PL2. The first plane PL1 is along a first direction D1 and a second direction D2 that crosses the first direction D1.

The second plane PL2 is along the second direction D2 and a third direction D3. The third direction D3 crosses a plane including the first direction D1 and the second direction D2. Alternatively, the second plane PL2 is along the first direction D1 and the second direction D2. In a case where the second plane PL2 is along the first direction D1 and the second direction D2, the second plane PL2 may be regarded as the third plane PL3 described above.

As described with reference to FIG, 3, the first plane PL1 includes the first region p1 and the first other region q1. The direction from the first region p1 to the first other region q1 is along the first direction D1. The first magnetic field data 11D includes the first region data Dp1 related to the first region p1 and the first other region data Dq1 related to the first other region q1.

In the inspection method according to the embodiment, the inspection target 80 is inspected based on the derived data Dr1. The derived data Dr1 includes the first inspection data DD1 and the second inspection data DD2. The first inspection data DD1 includes the first difference between the first other region inverted data Dqx1 obtained by inverting the first other magnetic field value included in the first other region data Dq1 in the first direction D1, and the first region data Dp1. The second inspection data DD2 is based on the second magnetic field data 12D. According to the embodiment, it is possible to provide an inspection method capable of performing highly accurate inspection.

In a case where the second plane PL2 is along the second direction D2 and the third direction D3, the data inversion described with reference to FIG. 7 may be applied. For example, the second plane PL2 includes the second region p2 and the second other region q2. The direction from the second region p2 to the second other region q2 is along the first crossing direction Dx1 that crosses the first direction D1. The second magnetic field data 12D includes the second region data Dp2 related to the second region p2 and the second other region data Dq2 related to the second other region q2. The second inspection data DD2 includes a second difference between the second other region inverted data obtained by inverting the second other magnetic field value included in the second other region data Dq2 in the first crossing direction Dx1 and the second region data Dp2.

In the second embodiment, the second plane PL2 may include the second position a2, the second opposing position b2, and the second other position c2. The second other position c2 may be a second midpoint between the second position a2 and the second opposing position b2 in the first crossing direction Dx1. The second region p2 is between the second position a2 and the second other position c2 in the first crossing direction Dx1. The second other region q2 is between the second other position c2 and the second opposing position b2 in the first crossing direction Dx1.

In another example, in a case where the second plane PL2 is along the first direction D1 and the second direction D2, the inspection target 80 may be between the second plane PL2 and the first plane PL1.

In the second embodiment, for example, the first magnetic field data 11D may relate to a component in the second direction D2. The inspection target 80 may be a battery 80C. The battery 80C includes the first electrode 81, the second electrode 82, and the battery portion 83 between the first electrode 81 and the second electrode 82. The direction from the first electrode 81 to the second electrode 82 is along the first direction D1. For example, the first magnetic field data 11D may include the distribution of the magnetic field generated from the battery 80C when an AC voltage (AC signal) is applied between the first electrode 81 and the second electrode 82.

### Third Embodiment

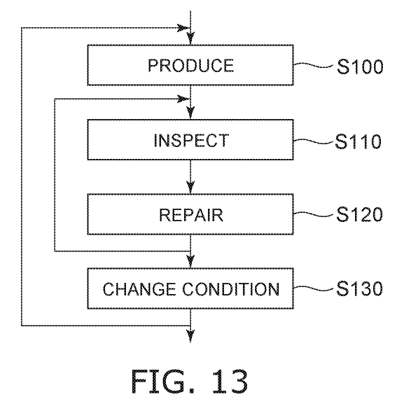

FIG. 13 is a flow chart illustrating a method for manufacturing a battery according to the third embodiment.

As shown in FIG. 13, a battery 80C to be an inspection target 80 is produced (step S100). The battery 80C is inspected by the inspection method according to the second embodiment (step S110). In the inspection, the processes described in relation to the first embodiment and the second embodiment may be carried out. Highly accurate inspection can be performed.

For example, battery 80C may include a first electrode 81, a second electrode 82, and a battery portion 83 between the first electrode 81 and the second electrode 82. The direction from the first electrode 81 to the second electrode 82 is along the first direction D1 of the first magnetic field data 11D. For example, the first magnetic field data 11D includes the distribution of the magnetic field generated from battery 80C when an AC voltage is applied between the first electrode 81 and the second electrode 82.

As shown in FIG. 13, repair may be performed based on the inspection results (step S120). The inspection target 80 (battery 80C) after repair may be inspected again.

As shown in FIG. 13, conditions may be changed based on the inspection results (step S130). For example, the conditions may include the formation conditions of the battery 80C. For example, the change in conditions may include the change in the material of the battery 80C. For example, the change in conditions may include the design change of the battery 80C. The inspection device 110 and inspection method according to the embodiment may be used for defect analysis of the inspection target 80.

The embodiments may include the following Technical proposals:

### Technical proposal 1

An inspection device, comprising:

an acquisitor configured to acquire data obtained from an inspection target; and

a processor configured to perform a first operation of processing the data acquired by the acquisitor,

the data including

a first magnetic field data related to a first plane, and

a second magnetic field data related to a second plane,

the first plane being along a first direction and a second direction crossing the first direction,

the second plane being along the second direction and a third direction,

the third direction crossing a plane including the first direction and the second direction,

the first plane including a first region and a first other region,

a direction from the first region to the first other region being along the first direction,

the first magnetic field data including a first region data related to the first region and a first other region data related to the first other region,

the processor being configured to inspect the inspection target based on derived data in the first operation, and

the derived data including:

a first inspection data including a first difference between the first region data and a first other region inverted data obtained by inverting a first other magnetic field value included in the first other region data in the first direction; and

a second inspection data based on the second magnetic field data.

### Technical proposal 2

The inspection device according to Technical proposal 1, wherein

the first plane includes a first position, a first opposing position, and a first other position,

the first other position is a first midpoint between the first position and the first opposing position in the first direction,

the first region is between the first position and the first other position in the first direction, and

the first other region is between the first other position and the first opposing position in the first direction.

### Technical proposal 3

The inspection device according to Technical proposal 1 or 2, wherein

the second plane includes a second region and a second other region,

a direction from the second region to the second other region is along a first crossing direction that crosses the first direction,

the second magnetic field data includes a second region data related to the second region and a second other region data related to the second other region, and

the second inspection data includes a second difference between the second region data and second other region inverted data obtained by inverting a second other magnetic field value included in the second other region data in the first crossing direction.

### Technical proposal 4

The inspection device according to Technical proposal 3, wherein

the second plane includes a second position, a second opposing position, and a second other position,

the second other position is a second midpoint between the second position and the second opposing position in the first crossing direction,

the second region is between the second position and the second other position in the first crossing direction, and

the second other region is between the second other position and the second opposing position in the first crossing direction.

### Technical proposal 5

The inspection device according to Technical proposal 3 or 4, wherein

the data further includes a third magnetic field data related to a third plane,

the third plane is along the first direction and the second direction,

the inspection target is between the first plane and the third plane,

the third plane includes a third region and a third other region,

a direction from the third region to the third other region is along the first direction,

the third magnetic field data includes a third region data related to the third region and a third other region data related to the third other region, and

the derived data further includes third inspection data including a third difference between the third region data and third other region inverted data obtained by inverting the third other magnetic field value included in the third other region data in the first direction.

### Technical proposal 6

The inspection device according to Technical proposal 5, wherein

the third plane includes a third position, a third opposing position, and a third other position,

the third other position is a third midpoint between the third position and the third opposing position in the first direction,

the third region is between the third position and the third other position in the first direction, and

the third other region is between the third other position and the third opposing position in the first direction.

### Technical proposal 7

The inspection device according to Technical proposal 5 or 6, wherein

the data further includes a fourth magnetic field data related to a fourth plane,

the fourth plane is along the second direction and the third direction,

the inspection target is between the fourth plane and the second plane,

the fourth plane includes a fourth region and a fourth other region,

a direction from the fourth region to the fourth other region is along the first crossing direction,

the fourth magnetic field data includes a fourth region data related to the fourth region and a fourth other region data related to the fourth other region,

the derived data further includes a fourth inspection data including a fourth difference between the fourth region data and fourth other region inverted data obtained by inverting a fourth other magnetic field value included in the fourth other region data in the first crossing direction.

### Technical proposal 8

The inspection device according to Technical proposal 7, wherein

the fourth plane includes a fourth position, a fourth opposing position, and a fourth other position,

the fourth other position is a fourth midpoint between the fourth position and the fourth opposing position in the first crossing direction,

the fourth region is between the fourth position and the fourth other position in the first crossing direction, and

the fourth other region is between the fourth other position and the fourth opposing position in the first crossing direction.

### Technical proposal 9

An inspection device, comprising:

an acquisitor configured to acquire data obtained from an inspection target; and

a processor configured to perform a first operation to process the data acquired by the acquisitor,

the data including

a first magnetic field data related to a first plane, and

a third magnetic field data related to a third plane, the first plane being along a first direction and a second direction crossing the first direction,

the third plane being along the first direction and the second direction,

the inspection target being between the first plane and the third plane,

the first plane including a first region and a first other region,

a direction from the first region to the first other region being along the first direction,

the first magnetic field data including a first region data related to the first region and a first other region data related to the first other region,

the processor being configured to inspect the inspection target based on derived data in the first operation,

the derived data including:

a first inspection data including a first difference between the first region data and a first other region inverted data obtained by inverting a first other magnetic field value included in the first other region data in the first direction, and

a third inspection data based on the third magnetic field data.

### Technical proposal 10

The inspection device according to Technical proposal 9, wherein

the first plane includes a first position, a first opposing position, and a first other position,

the first other position is a first midpoint between the first position and the first opposing position in the first direction,

the first region is between the first position and the first other position in the first direction, and

the first other region is between the first other position and the first opposing position in the first direction.

### Technical proposal 11

The inspection device according to Technical proposal 9 or 10, wherein

the third plane includes a third region and a third other region,

a direction from the third region to the third other region is along the first direction,

the third magnetic field data includes a third region data related to the third region and a third other region data related to the third other region,

the data based on the third magnetic field data includes a third inspection data including a third difference between the third region data and a third other region inverted data obtained by inverting a third other magnetic field value included in the third other region data in the first direction.

### Technical proposal 12

The inspection device according to Technical proposal 11, wherein

the third plane includes a third position, a third opposing position, and a third other position,

the third other position is a third midpoint between the third position and the third opposing position in the first direction,

the third region is between the third position and the third other position in the first direction, and

the third other region is between the third other position and the third opposing position in the first direction.

### Technical proposal 13

The inspection device according to any one of Technical proposals 1 to 12, wherein

the first magnetic field data relates to a component in the second direction.

### Technical proposal 14

The inspection device according to any one of Technical proposals 1 to 13, wherein

the inspection target is a battery.

### Technical proposal 15

The inspection device according to Technical proposal 14, wherein

the battery includes a first electrode, a second electrode, and a battery portion between the first electrode and the second electrode, and

a direction from the first electrode to the second electrode is along the first direction.

### Technical proposal 16

The inspection device according to Technical proposal 15, wherein

the first magnetic field data includes a distribution of the magnetic field generated from the battery when an AC voltage is applied between the first electrode and the second electrode.

### Technical proposal 17

An inspection method, comprising:

acquiring data obtained from an inspection target;

processing the data,

the data including

a first magnetic field data related to a first plane, and

a second magnetic field data related to a second plane,

the first plane being along a first direction and a second direction crossing the first direction,

the second plane being along the second direction and a third direction or along the first direction and the second direction,

the third direction crossing a plane including the first direction and the second direction,

the first plane including a first region and a first other region,

a direction from the first region to the first other region being along the first direction,

the first magnetic field data including a first region data related to the first region and a first other region data related to the first other region; and

inspecting the inspection target based on a derived data;

the derived data including:

a first inspection data including a first difference between the first region data and a first other region inverted data obtained by inverting a first other magnetic field value included in the first other region data in the first direction, and

a second inspection data based on the second magnetic field data.

### Technical proposal 18

The inspection method according to Technical proposal 17, wherein

the second plane is along the first direction and the second direction, and

the inspection target is between the second plane and the first plane.

### Technical proposal 19

A method for manufacturing a battery, comprising:

producing the battery to be the inspection target; and

inspecting the battery using the inspection method according to Technical proposal 17 or 18.

### Technical proposal 20

The method for manufacturing the battery according to Technical proposal 19, wherein

the battery includes a first electrode, a second electrode, and a battery portion between the first electrode and the second electrode, and

a direction from the first electrode to the second electrode is along the first direction.

According to the embodiment, an inspection device, an inspection method, and a method for manufacturing a battery capable of performing highly accurate inspection can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the inspection devices such as acquisitors, processors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all inspection devices, all inspection methods, and all methods for manufacturing batteries practicable by an appropriate design modification by one skilled in the art based on the inspection devices, inspection methods, and methods for manufacturing batteries described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An inspection device, comprising:
an acquisitor configured to acquire data obtained from an inspection target; and
a processor configured to perform a first operation of processing the data acquired by the acquisitor,
the data including
a first magnetic field data related to a first plane, and
a second magnetic field data related to a second plane,
the first plane being along a first direction and a second direction crossing the first direction,
the second plane being along the second direction and a third direction,
the third direction crossing a plane including the first direction and the second direction,
the first plane including a first region and a first other region,
a direction from the first region to the first other region being along the first direction,
the first magnetic field data including a first region data related to the first region and a first other region data related to the first other region,
the processor being configured to inspect the inspection target based on derived data in the first operation, and
the derived data including:
a first inspection data including a first difference between the first region data and a first other region inverted data obtained by inverting a first other magnetic field value included in the first other region data in the first direction; and
a second inspection data based on the second magnetic field data.

2. The inspection device according to claim 1, wherein
the first plane includes a first position, a first opposing position, and a first other position,
the first other position is a first midpoint between the first position and the first opposing position in the first direction,
the first region is between the first position and the first other position in the first direction, and
the first other region is between the first other position and the first opposing position in the first direction.

3. The inspection device according to claim 1, wherein
the second plane includes a second region and a second other region,
a direction from the second region to the second other region is along a first crossing direction that crosses the first direction,
the second magnetic field data includes a second region data related to the second region and a second other region data related to the second other region, and
the second inspection data includes a second difference between the second region data and second other region inverted data obtained by inverting a second other magnetic field value included in the second other region data in the first crossing direction.

4. The inspection device according to claim 3, wherein
the second plane includes a second position, a second opposing position, and a second other position,
the second other position is a second midpoint between the second position and the second opposing position in the first crossing direction,
the second region is between the second position and the second other position in the first crossing direction, and
the second other region is between the second other position and the second opposing position in the first crossing direction.

5. The inspection device according to claim 3, wherein
the data further includes a third magnetic field data related to a third plane,
the third plane is along the first direction and the second direction,
the inspection target is between the first plane and the third plane,
the third plane includes a third region and a third other region,
a direction from the third region to the third other region is along the first direction,
the third magnetic field data includes a third region data related to the third region and a third other region data related to the third other region, and
the derived data further includes third inspection data including a third difference between the third region data and third other region inverted data obtained by inverting the third other magnetic field value included in the third other region data in the first direction.

6. The inspection device according to claim 5, wherein
the third plane includes a third position, a third opposing position, and a third other position,
the third other position is a third midpoint between the third position and the third opposing position in the first direction,
the third region is between the third position and the third other position in the first direction, and
the third other region is between the third other position and the third opposing position in the first direction.

7. The inspection device according to claim 5, wherein
the data further includes a fourth magnetic field data related to a fourth plane,
the fourth plane is along the second direction and the third direction,
the inspection target is between the fourth plane and the second plane,
the fourth plane includes a fourth region and a fourth other region,
a direction from the fourth region to the fourth other region is along the first crossing direction,
the fourth magnetic field data includes a fourth region data related to the fourth region and a fourth other region data related to the fourth other region,
the derived data further includes a fourth inspection data including a fourth difference between the fourth region data and fourth other region inverted data obtained by inverting a fourth other magnetic field value included in the fourth other region data in the first crossing direction.

8. The inspection device according to claim 7, wherein
the fourth plane includes a fourth position, a fourth opposing position, and a fourth other position,
the fourth other position is a fourth midpoint between the fourth position and the fourth opposing position in the first crossing direction,
the fourth region is between the fourth position and the fourth other position in the first crossing direction, and
the fourth other region is between the fourth other position and the fourth opposing position in the first crossing direction.

9. An inspection device, comprising:
an acquisitor configured to acquire data obtained from an inspection target; and
a processor configured to perform a first operation to process the data acquired by the acquisitor,
the data including
a first magnetic field data related to a first plane, and
a third magnetic field data related to a third plane,
the first plane being along a first direction and a second direction crossing the first direction,
the third plane being along the first direction and the second direction,
the inspection target being between the first plane and the third plane,
the first plane including a first region and a first other region,
a direction from the first region to the first other region being along the first direction,
the first magnetic field data including a first region data related to the first region and a first other region data related to the first other region,
the processor being configured to inspect the inspection target based on derived data in the first operation,
the derived data including:
a first inspection data including a first difference between the first region data and a first other region inverted data obtained by inverting a first other magnetic field value included in the first other region data in the first direction, and
a third inspection data based on the third magnetic field data.

10. The inspection device according to claim 9, wherein
the first plane includes a first position, a first opposing position, and a first other position,
the first other position is a first midpoint between the first position and the first opposing position in the first direction,
the first region is between the first position and the first other position in the first direction, and
the first other region is between the first other position and the first opposing position in the first direction.

11. The inspection device according to claim 9, wherein
the third plane includes a third region and a third other region,
a direction from the third region to the third other region is along the first direction,
the third magnetic field data includes a third region data related to the third region and a third other region data related to the third other region,
the data based on the third magnetic field data includes a third inspection data including a third difference between the third region data and a third other region inverted data obtained by inverting a third other magnetic field value included in the third other region data in the first direction.

12. The inspection device according to claim 11, wherein
the third plane includes a third position, a third opposing position, and a third other position,
the third other position is a third midpoint between the third position and the third opposing position in the first direction,
the third region is between the third position and the third other position in the first direction, and
the third other region is between the third other position and the third opposing position in the first direction.

13. The inspection device according to claim 1, wherein
the first magnetic field data relates to a component in the second direction.

14. The inspection device according to claim 1, wherein
the inspection target is a battery.

15. The inspection device according to claim 14, wherein
the battery includes a first electrode, a second electrode, and a battery portion between the first electrode and the second electrode, and
a direction from the first electrode to the second electrode is along the first direction.

16. The inspection device according to claim 15, wherein
the first magnetic field data includes a distribution of the magnetic field generated from the battery when an AC voltage is applied between the first electrode and the second electrode.

17. An inspection method, comprising:
acquiring data obtained from an inspection target;
processing the data,
the data including
a first magnetic field data related to a first plane,
and
a second magnetic field data related to a second plane,
the first plane being along a first direction and a second direction crossing the first direction,
the second plane being along the second direction and a third direction or along the first direction and the second direction,
the third direction crossing a plane including the first direction and the second direction,
the first plane including a first region and a first other region,
a direction from the first region to the first other region being along the first direction,
the first magnetic field data including a first region data related to the first region and a first other region data related to the first other region; and
inspecting the inspection target based on a derived data;
the derived data including:
a first inspection data including a first difference between the first region data and a first other region inverted data obtained by inverting a first other magnetic field value included in the first other region data in the first direction, and
a second inspection data based on the second magnetic field data.

18. The inspection method according to claim 17, wherein
the second plane is along the first direction and the second direction, and
the inspection target is between the second plane and the first plane.

19. A method for manufacturing a battery, comprising:
producing the battery to be the inspection target; and
inspecting the battery using the inspection method according to claim 17.

20. The method for manufacturing the battery according to claim 19, wherein
the battery includes a first electrode, a second electrode, and a battery portion between the first electrode and the second electrode, and
a direction from the first electrode to the second electrode is along the first direction.
